(19) United States
(12) Patent Application Publication
(10) Pub. No.: US 2025/0232527 A1
(43) Pub. Date: Jul. 17, 2025

(54) AI-ASSISTED CREATION OF 3D BUILDING MODELS

(71) Applicant: Digs Space, Inc., Vancouver, WA (US)

(72) Inventors: Nicholas DeGroot, Vancouver, WA (US); Ryan Fink, Vancouver, WA (US); Pavan Kamaraju, Vancouver, WA (US); Jason Goetz, Vancouver, WA (US); Ty Frackiewicz, Vancouver, WA (US)

(73) Assignee: Digs Space, Inc., Vancouver, WA (US)

(21) Appl. No.: 18/434,171

(22) Filed: Feb. 6, 2024

Related U.S. Application Data
(60) Provisional application No. 63/620,715, filed on Jan. 12, 2024.

(51) Int. Cl. G06T 17/00; G06T 7/12; G06T 11/00

(52) U.S. Cl. CPC G06T 17/00; G06T 7/12; G06T 11/00

(57) ABSTRACT

Systems and methods allow prediction of semantic information and generation of a 3D model from one or more raster images of a structure. In embodiments, the raster images may be converted to vector images, and received semantic information may be used for generation of predicted semantic information. The combination of provided and predicted semantic information, along with the vector images, can facilitate generation of a 3D model that is scale-accurate to the structure illustrated by the raster images. Other embodiments may be described and/or claimed.

### CROSS-REFERENCE TO RELATED APPLICATIONS

This application claims priority to U.S. Provisional Application No. 63/620,715, filed on 12 Jan. 2024, the contents of which are incorporated by this reference as if set forth fully herein.

### TECHNICAL FIELD

Disclosed embodiments are directed to building information systems, and specifically to techniques for generating and updating a 3D model of a building from various information sources.

### BACKGROUND

Construction of a structure such as a house or commercial building involves input and/or contributions from a wide variety of different sources. Structures typically originate with a set of blueprints or similar plans which provide the basic dimensions of the building, and may specify various structural components. Such blueprints or floor layouts may be obtained from any suitable source. The plans, or subsequent documentation from various subcontractors, can also include information about various building systems such as electrical, telecommunications, plumbing including water and sewage, and heating/ventilation/air conditioning (HVAC), to name a few trades. This information may include data on various structures that may not be readily visible in a completed building. This collection of information can also be useful over the life of its associated structure, to assist with maintenance and repairs, as well as aiding any subsequent modifications, renovations, and/or remodeling. As a result, such plans and documentation are typically kept safe so as to be available for the lifetime of the structure. With computer systems becoming ubiquitous, such information can increasingly be stored and managed in a digital format.

To improve the usefulness of construction blueprints or plans, the subsequent documentation may also be integrated into the blueprints or plans to provide a more holistic view of a structure at all stages of construction and over the structure's lifetime. Changes to the plans and/or subsequent documentation may further be updated at any time during the structure's lifetime to ensure that an accurate record of the structure and its associated fixtures is maintained to facilitate any future repairs and/or renovations.

The background description provided herein is for the purpose of generally presenting the context of the disclosure. Unless otherwise indicated herein, the materials described in this section are not prior art to the claims in this application and are not admitted to be prior art by inclusion in this section.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an example process flow for generating a 3D building model from floor plans and semantic information, according to various embodiments.

FIG. 2 depicts an example device displaying an image of a wall, with augmented reality features superimposed over the image illustrating hidden structures reflecting semantic information, according to various embodiments.

FIGS. 3A and 3B depicts an example set of 2D floor plans that include semantic information, according to various embodiments.

FIG. 4 depicts a process flow for using a set of 2D floor plans and semantic information to generate a 3D model of the structure depicted in the floorplans.

FIG. 5 is a flowchart of the operations of an example method for generating a 3D model of a structure from a set of 2D floor plans and associated semantic information, according to various embodiments.

FIG. 6 is a block diagram of an example computer that can be used to implement some or all of the components of the disclosed systems and methods, according to various embodiments.

FIG. 7 is a block diagram of a computer-readable storage medium that can be used to implement some of the components of the system or methods disclosed herein, according to various embodiments.

### DETAILED DESCRIPTION

Floorplans, which may be 2D layouts, are typically rasterized or converted into a grid of pixels, for sharing in print or digital media. Typically, when the initial layouts are in a recognized CAD format or another vector format, the conversion process strips away structured geometric and semantic information with which it was created, such as dimensional information and/or metadata indicating the nature of various structures and markings within the floorplan. This information is essential for human postprocessing, such as measuring distances, identifying objects, or making modifications. Even if floorplans are stored as vectorized pieces in PDFs, they may still be missing at least some rich semantic information, such as metadata associated with various features, e.g. electrical fixtures, appliances, mechanical systems, etc. Other such information may include heights of ceilings, which may not be displayed or indicated on rasterized 2D layouts.

The loss of structured geometric and semantic information can limit the ability to perform further computations on floorplans, such as model analysis, synthesis, or modification. For example, it may be difficult to use a rasterized floorplan to generate a 3D model of a structure or to identify the different rooms in a floorplan. Room information may provide key context to determining the nature of indicated features and/or to fill in informational gaps. Accurate 3D model generation further requires height information to properly render vertical aspects of the structure. Recovering this information is a hard task and has been long studied by various research groups.

Disclosed embodiments are directed to techniques for generating a 3D model of a structure from 2D plans that have been rasterized or otherwise converted from a vector or similar format into a raster format, such as an image file. In some embodiments, a rasterized 2D image is processed through artificial intelligence (AI) that is trained to understand floorplans, which predicts and/or extrapolates any semantic information that is missing or otherwise may have been lost. This processed image is segmented and created into a vector form, and the predicted semantic information is applied to the vector form. With the vector form and reconstructed semantic information, a 3D model may be constructed.

In some embodiments, existing and/or additional semantic information may be pulled in from other plans, such as electrical drawings, mechanical drawings, plumbing drawings, appliance locations, etc.

In some embodiments, the artificial intelligence may be in the form of an artificial neural network (ANN), which may be trained on custom datasets that facilitate the extrapolation or prediction of semantic information. The datasets, in some embodiments, may encompass best building practices so that the 3D model reflects a structure that complies with construction industry standards and best practices.

In other embodiments, the resulting vector plans may be subsequently updated or modified by ingestion of revised plans and/or additional semantic information.

In still other embodiments, information may be obtained from a user mobile device that may directly scan a physical space associated with the structure, such as the structure under construction or following construction, and use the scan to either update the existing vector plans, or to generate new vector plans in the absence of an initial 2D raster image. The mobile device scans may also be processed to predict semantic information, such as detection of lights, switches, faucets, vents, appliances, etc., which can be used to predict semantic information and associate it with a vector plan.

In yet other embodiments, the resulting 3D model may be tagged or associated with additional data, such as user-uploaded data, warranty information, product manuals, service information, maintenance records, product specifications, etc. Such information may be processed using AI, which may automatically tag or associate the additional data to the appropriate aspects of the 3D model.

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Aspects of the disclosure are disclosed in the accompanying description. Alternate embodiments of the present disclosure and their equivalents may be devised without parting from the spirit or scope of the present disclosure. It should be noted that like elements disclosed below are indicated by like reference numbers in the drawings.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

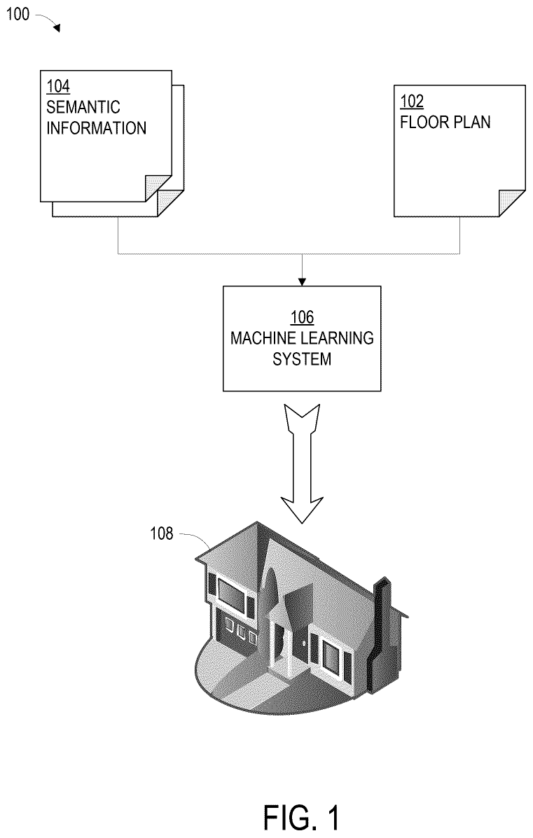

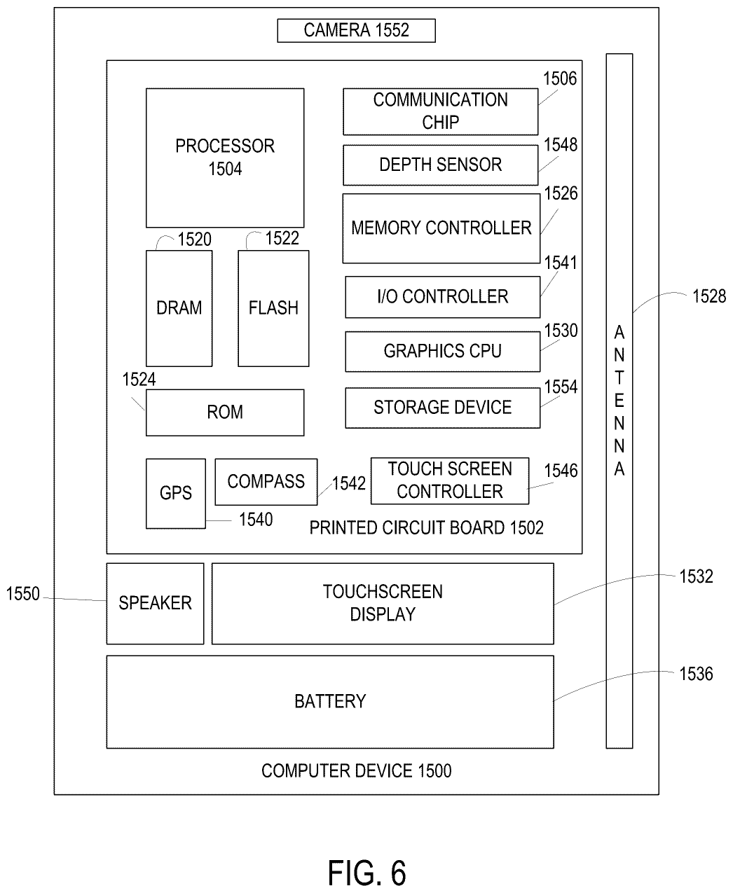

FIG. 1 illustrates a process flow 100 for integrating structure design plans and associated specifications and other related information to generate a digital twin, according to various embodiments. In process flow 100, a floor plan 102 provides the design for a structure, and may be combined with any available semantic information 104. The floor plan 102 and any information 104 are provided to a machine learning system 106, which then generates a 3D model 108 that integrates the specifications and information 104 with the floor plan 102. Furthermore, the machine learning system 106 may extrapolate or otherwise predict semantic information from the floor plan 102 and/or information 104 where neither explicitly provides complete semantic information. The 3D model 108, then, effectively acts as a digital twin of the physical building to be constructed according to the floor plan 102 and information 104. Process flow 100 may be implemented on a single device, such as a computer device 1500 (FIG. 6) that may implement a laptop, desktop, server, or mobile device, or on multiple devices, such as a cloud computing facility or data center.

In some embodiments, process flow 100 may be implemented in parts on multiple different devices. For example, floor plan 102 and information 104 may be received and at least partially processed on a first device, processing with a machine learning system 106 may occur on a second device such as a remote server, and rendering of the 3D model 108 may occur on a third device. In another example, floor plan 102 may be scanned or ingested using a first device, with the semantic information 104 obtained from a second device, with the first and second devices in communication with a remote server that executes the machine learning system 106 and outputs the 3D model 108. The 3D model 108 may further be provided back to one or more of the first or second devices for viewing. Other variations may be possible while keeping within the scope of this disclosure.

In some embodiments, the floor plan 102 may be any suitable set of plans as may be accepted and/or commonly used in the construction industry. For example, in some embodiments, floor plan 102 may be plans drawn up by an architect or contractor. The floor plan 102 may be two-dimensional plans, as typically used in many constructions projects. In embodiments, the floor plan 102 may further include various visible markings that indicate scale, dimensions, locations of various features, materials specifications, and/or other information relevant to the construction of the structure. A non-exhaustive list of possible structural aspects provided by floor plan 102 was discussed above. The floor plan 102 may be provided in any suitable raster format, such as an image (e.g. bitmap, TIFF, JPEG, PNG, etc.), PDF, or another known or commonly used raster file format. In some scenarios, the floor plan 102 may be in a paper format, in which the floor plan 102 will need to be scanned or otherwise digitized, and placed into a suitable format. In some embodiments, the floor plan 102 may be in multiple different formats. In still other embodiments, the floor plan 102 may be provided in a vector format or another suitable architectural format, but may lack some or all semantic information.

In other embodiments, such as where architectural plans of a building are not available, floor plan 102 may instead be obtained using a scan of an area. For example, a device may be equipped to generate a layout of a space. Any suitable technique may be employed to obtain such a scan, such as a LiDAR scan, photogrammetry, simultaneous localization and mapping (SLAM) techniques, direct depth measurement, or any suitable technique now known or later developed, or a combination of any of the foregoing.

The semantic information 104 may be any information or type of information that is relevant to the structure being constructed, pursuant to floor plan 102. In embodiments, information 104 may include information about building structures and/or equipment that would not otherwise be visible, such as electrical wiring, plumbing, HVAC duct work, framing elements, insulation, etc. In other embodiments, information 104 may include information instructive or relevant to rendering of the 3D model 108, such as one or more inventory lists of various supplies, building materials, appliances, specifications of exterior finishes, e.g. paint and/or stain type; lighting; HVAC specifications and systems; flooring; siding; stone, rock and/or wood features, such as fireplaces; and fixtures such as cabinetry and shelving. This list should be considered as an example, and should not be construed as limiting or exhaustive. As with the floor plan 102, the information 104 may be supplied in a digital format such as image files, text files, PDF files, HTML files, XML files, Excel files or other standard office program formats, and/or another suitable file type. Where information 104 is in a hard copy format, the information 104 would need to be digitized, such as by scanning, and possibly processed through some form of character and/or object recognition. In embodiments, information 104 may be provided in a variety of different formats. For example, where information 104 comes from a number of different vendors, each vendor may supply information 104 in a different format or multiple different formats. In embodiments, the semantic information 104 is incomplete for purposes of creating a 3D model that is a true representation of the structure presented in the floor plan 102.

In embodiments, the floor plan 102 and the available semantic information 104 are inputted into the machine learning system 106 via any suitable interface, depending upon the needs of a given implementation. Accordingly, the floor plan 102 and information 104 must be in a format with which the machine learning system 106 can interact. Suitable formats may include, but are not limited to, PDF files, image files, text files, HTML files, XML files, CAD files, and/or another suitable file type. The specific type or types of acceptable format(s) will depend upon the specifics of a given implementation of the machine learning system 106. Machine learning system 106 may perform varying degrees of preprocessing depending upon the particular type of file input into system 106. In some embodiments, a separate pre-processor (not shown) may precede the machine learning system 106 and/or be part of the machine learning system 106 to convert or otherwise process the various files input into a common format or suitable intermediate format useable by the system 106.

As mentioned above, in embodiments the machine learning system 106 may be trained to extrapolate or predict semantic information that may be missing from the floor plan 102 and the semantic information 104. For example, the floor plan 102 and information 104 may indicate the existence of a light and a ceiling fan in a room, and the presence of a switch next to each of two doors. The machine learning system 106, which may be trained on semantic information that includes electrical wiring standards and practices, may be able to predict that each indicated switch has controls for both the light and the ceiling fan, and that each switch is wired in a three-way configuration so that either can control both the light and ceiling fan. Furthermore, depending on the type of ceiling fan and/or any switch specifications, the machine learning system 106 may be able to predict whether the switch will allow for control of fan speed, or simple on-off, whether the switch can dim the lighting, or even whether a single gang control can control all aspects of the fan and light, or if the fan requires a separate wall control.

Other examples of predicted semantics may be the existence of 240 Volt outlets and/or gas plumbing in a laundry or utility area based on a given selected model of dryer. Where building plans may indicate the presence of a dryer but not specify gas or electric, if the machine learning system 106 is also informed of the model of dryer being installed, it may be able to determine whether the laundry or utility area requires a 240V outlet or plumbing for a gas connection. This predicted semantic information may then be made visible on the resulting 3D model 108.

The interface into the machine learning system 106 may be any suitable interface that can accept files and forward them to the machine learning system 106 or pre-processor for input into the machine learning system 106. For example, in some embodiments, a drag and drop interface may be employed, such as is commonly found on many web browser interfaces for cloud computing systems. The interface may be part of an interface that also allows viewing and/or interaction with the 3D model 108 and associated information, as will be discussed in greater detail below.

Once the various data comprising floor plan 102 and semantic information 104 have been supplied and any necessary preprocessing is complete, machine learning system 106 may then, in embodiments, process the various input files to extract relevant information and create the 3D model 108 (hereinafter, “digital model”; “virtual model” is synonymous). In embodiments, the information may be extracted and the 3D model 108 built using a machine learning process or algorithm such as an artificial neural network (ANN). Any suitable type of ANN as is now known or later developed may be used to implement learning system 106, depending on the needs of a given embodiment. In some embodiments, multiple ANNs of a similar or different type may be employed. For example, an ANN may be used to act as a preprocessor, such as for extracting relevant information, with a second ANN employed to generate the 3D model 108 from the floor plan 102. Selection of an appropriate ANN may depend upon a number of factors, with selection of ANN size and configuration intended to minimize overfitting or underfitting.

The ANN used to implement the machine learning system 106 may be initially trained using a collection or training set of a variety of different types of building-related information. The training set may include a variety of blueprints and/or building scans (such as scans of the interiors of buildings), such as would be considered examples of floor plan 102, as well as a wide variety of building-related information, such as would be considered examples of semantic information 104. The blueprints and/or building scans of the training set may be input into the ANN and compared with an associated desired outcome that is also part of the training set. Furthermore, the machine learning system 106 may be further trained on industry-accepted building practices, such as electrical codes, plumbing codes, framing codes, contractor- or builder-specific practices, local or regional requirements (e.g., insulation and structural requirements in Alaska, which experiences earthquakes and severely cold winters, will necessarily be different than such requirements in Florida, which experiences significant heat and hurricanes), and any other pertinent information that is useful in allowing an implementing system to accurately predict or extrapolate unknown semantic information.

In embodiments, the desired outcome may be a reference 3D model of the building represented by a particular set of blueprints or scans that may include various kinds or items of predicted semantic information that are missing from the corresponding example floor plan and semantic information. In the training process, the training set is passed through the machine learning system 106, and the resulting 3D model and extrapolated or predicted semantic information is compared against the desired outcome as embodied in the reference 3D model. A difference between the result and the reference models is determined, which may then be used to adjust various weights and/or parameters of the ANN implementing the machine learning system 106. The process of passing the training set through the machine learning system 106, comparison against the reference 3D model and associated predicted semantic information, and adjustment of weights may continue iteratively (generally known as epochs) until further iterations fail to yield any substantive improvements in accuracy, at which point the machine learning system 106 may be considered trained.

The trained machine learning system 106 may then be validated on a validation or test set. The test set may be similar to the training set insofar as it includes target 3D models that correspond with the test set floor plans, but with a different collection of floor plans. If the training set used to train the machine learning system 106 is sufficiently comprehensive and an appropriate ANN was selected, the test set should result in predicted 3D models and semantic information that are close to the test set target 3D models, within an acceptable accuracy range comparable to the accuracy achieved following the training process. Use of the test set may also help reveal cases of overfitting, where an ANN has too many parameters and so simply “memorizes” the training set, as opposed to being configured to make trend predictions. For example, if an ANN is selected that has a number of tunable parameters that approaches the number of entries in the training set, overfitting is increasingly likely to occur. A relatively high accuracy may be achieved on the training set, as each item is likely to take a distinct path through the ANN. However, parameters may not be sufficiently tuned as the abundance of nodes in the ANN allow accurate results to be achieved via distinct paths vs. having to tune parameters to accurately predict outcomes. As a result, the test set yields inaccurate predictions due to insufficient tuning. Employing an ANN with a smaller number of tunable parameters compared to the training set may yield better predictive capabilities. Conversely, too few tunable parameters (and nodes) can result in underfitting, where there are insufficient outputs to provide appropriately fine-grained predictions.

In some embodiments the ANN may be configured to feed back the results of each set of floor plan 102 and information 104 into the ANN as well as any adjustments made by a user (discussed below) to improve the accuracy of the machine learning system 106 over time. In such implementations, each floor plan and associated user adjustments can be thought of as providing additional training data, with the user providing validation of accuracy. While machine learning system 106 may be implemented using an ANN in some embodiments, this should not be construed to be limiting. Machine learning system 106 may be implemented using any technology, method, or technique suitable to convert floor plan 102 and information 104 into 3D model 108, and to predict or extrapolate semantic information that is not present in either floor plan 102 or information 104.

3D model 108 may be presented in a number of different formats, depending upon the specifics of a given embodiment. 3D model 108 may include a cartoon version, a photo realistic version, a genericized version where privacy is a consideration, and may be provided in 2D and/or 3D versions. Furthermore, 3D model 108 may, in embodiments, be usable to generate a variety of different types of representations of the structure formed from floor plan 102 and information 104. Various techniques may be used to view the semantic information 104, including any predicted or extrapolated information.

In embodiments, 3D model 108 may be rendered to provide an approximation of both the structure as defined by floor plan 102 as well as the various aspects provided by information 104. Thus, a 3D model 108 may reflect the floor plan and position of various features such as roof lines, windows, doors, and the position of various fixtures, as indicated by floor plan 102. The exterior and interior may be textured to reflect finish choices such as siding, roofing, masonry and/or stone features, flooring, and paint, as indicated by information 104. Fixtures indicated by floor plan 102 and/or information 104, or which may be predicted or extrapolated, such as plumbing fixtures, electrical fixtures, cabinetry, trim, and other fixtures may be rendered into 3D model 108. If provided by information 104, exterior features such as landscaping, walkways, water features, etc., and interior features such as appliances and/or furniture may be added to 3D model 108. As will be understood, any other information that is provided or can be extrapolated from floor plan 102 and information 104 may be used to create a relatively accurate 3D model 108. Depending on the needs of a given embodiment, more than one ANN (of similar or different types) may be employed to generate the various aspects of the 3D model 108.

3D model 108, in embodiments, may be presented in a user interface that allows for interaction with the model and/or to vary or modify the format presented, such as selecting from one or more of the example versions listed above. The user interface may further allow semantic information, both supplied and predicted or extrapolated, to be viewed, and/or 3D model 108 to be edited. Depending upon the type of interface used for interacting with the 3D model 108, various parts of information 104 or information derived from information 104 may be accessible to a user of the interface. For example, viewing an appliance presented in the 3D model 108 may allow the user to access information about the appliance, such as a manual, while viewing or inspecting a surface may allow the user to access information about the surface finish, e.g. paint color, siding type, flooring type, etc., depending upon the nature of the surface being viewed.

As mentioned above, where a user edits aspects of the 3D model 108, in some embodiments these changes may be propagated back to the ANN for further refinement, such as where a user indicates that their edits are due to improper predictions from the floor plan 102 and/or semantic information 104. Such back propagation may include corrections to predicted or extrapolated semantic information, particularly where the ANN did not predict or extrapolate information that aligns with accepted building practices, or where a particular structure has unique requirements that hinder accurate prediction or extrapolation. For example, a unique or custom structure may impose unique considerations for electrical, plumbing, HVAC, appliances, etc., that would not be found in typical or comparable structures, and so the ANN would not necessarily be able to accurately predict missing semantic information that would comport with such considerations. Back propagation of user corrections can help begin to train the ANN to provide more accurate semantic information predictions for unique structures, particularly where a given ANN is employed by a builder or similar entity that routinely constructs custom or unique structures. Thus, in such an embodiment, the ANN may be able to learn to accurately predict semantic information unique to its user over time.

It should be understood that process flow 100 may be used for both initial creation of the 3D model 108 as well as subsequent iterations and updates of 3D model 108. For example, once a 3D model 108 has been created, an owner of the structure represented by the 3D model 108 may utilize an implementation of process flow 100 at a later time to process additional and/or updated vendor specifications and information 104, and to extrapolate or predict additional missing semantic information. This additional and/or updated information 104 may be generated as part of a remodel or renovation of the structure, changing of appliances, altered exterior/interior finishes, additions/changes/deletions of fixtures, and/or other any other changes to the structure that are or should be reflected in the 3D model 108 to ensure it continues to accurately reflect its corresponding structure. Still further, a user of the 3D model 108 may be able to model or demo changes to various aspects on a temporary basis, such as exploring different finishes, paint colors, appliances, location of fixtures, etc., without needing to propagate such changes back to the stored model.

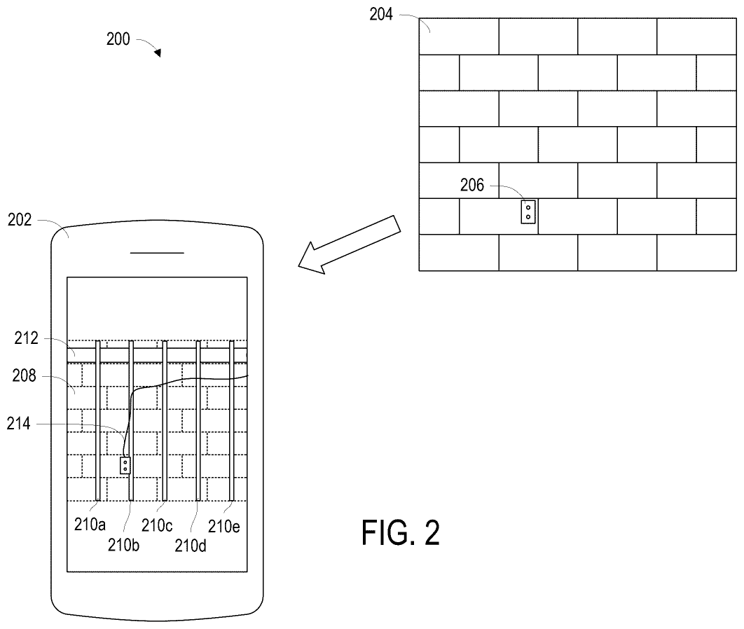

FIG. 2 illustrates an example view 200 of a portion of a structure and an overlaid view generated from a corresponding digital model (or digital twin, terms used interchangeably), which depicts how semantic information, either provided as part of floor plan 102 (FIG. 1) and/or semantic information 104 (FIG. 1) or extrapolated or predicted from the information 104, may be viewed. View 200 is illustrated on the display of a device 202, such as a smartphone, laptop, tablet, or other mobile device that is capable of displaying AR images. View 200 reflects a wall 204 of a building that has a corresponding structure or representation in a 3D model, such as 3D model 108 (FIG. 1). Wall 204 may enclose various structures such that they are not visible, but are known from the floor plan 102 and/or information 104 or may have been extrapolated or predicted from the same, and may accordingly be embedded in or otherwise associated with the 3D model 108 created via process flow 100 (FIG. 1).

When a user of device 202 is viewing a portion of wall 204, device 202 may be provided with information from the 3D model 108 about semantic information for the portion of the wall 204 that corresponds to the view on the display of device 202. In the depicted embodiment, device 202 is provided information about structures hidden within wall 204, including structural members 210a to 210e, plumbing 212, and electrical cabling 214, which are rendered and overlaid upon the depiction 208 of the wall 204. The information may, in embodiments, approximate the appearance of these various structures using any suitable representation, including AR objects. For example, structural members 210a to 210e, which may be studs, may be displayed as lumber in substantially the locations they would be found within the physical wall 204. Similarly, plumbing 212 and electrical cabling 214 may also be illustrated to approximate the appearance and location of the physical plumbing and cabling. The locations of the various objects superimposed upon depiction 208 may be synchronized with view of the wall 204 to closely correspond with the locations of the actual structures within wall 204.

These various structures and their depicted locations, such as structural members 210a to 210e, plumbing 212, and electrical cabling 214, may not have been directly supplied in either floor plan 102 or semantic information 104. For example floor plan 102 may indicate the presence and desired location of socket 206 on wall 204, as well as the location of various switches and/or electrical distribution panels connected to socket 206, within the structure. However, the presence and routing of electrical cabling 214 may not be explicitly depicted in floor plan 102 or described in semantic information 104. Thus, the ANN described above with reference to FIG. 1 may extrapolate the likely presence and position of electrical cabling 214 based upon the known or expected locations of other electrical fixtures, as well as an understanding of electrical code requirements. Likewise, the location of structural members 210a to 210e also may not have been depicted in floor plan 102, as floor plans often do not describe the position and arrangement of wall framing members. Floor plan 102 may only indicate wall dimensions and heights. Information about the structural members 210a to 210e, including number and location within the wall, thus may be predicted or extrapolated from structural framing practices that are widely accepted in the building industry. As mentioned above, where the position of such structures varies in implementation from the initial predictions, correct information may be fed back to an implementing system based on actual scans of the completed or partially completed wall.

In some embodiments, device 202 may receive the information for representation 208 from a remote server, such as server 108, or other repository of the 3D model 108 and associated semantic information 104. For example, device 202 may transmit its location and orientation to the remote server, which may then correlate the location and orientation to the corresponding portion of the 3D model 108. The device 202 may further transmit information about its current view properties, such as a view portal or window size, so that the remote server can determine what portion and associated structures of the 3D model 108 are currently in view of the device 202. With this information, the remote server can determine what information to transmit to the device 202 for display, the information corresponding to objects and structures currently in view of the camera of device 202.

In some embodiments, device 202 may include a local copy of the digital 3D model 108 and related semantic information 104, which may be accessed and/or displayed in a dedicated application that runs on device 202. In such embodiments, the device 202 may handle correlating its position and orientation within the local copy of the 3D model.

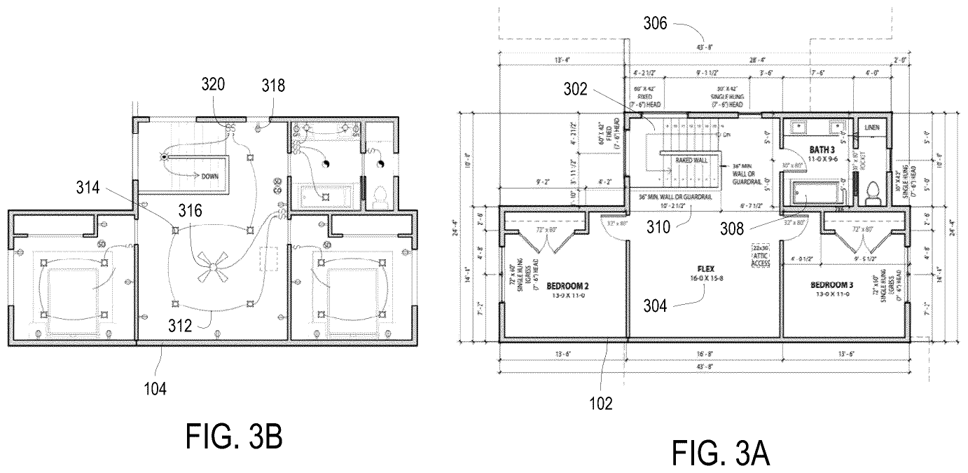

FIGS. 3A and 3B depict raster images of a floor plan 102 and associated example semantic information 104, respectively. The floor plan 102 depicted in FIG. 3A is for a single floor of a multiple level structure, indicated by the presence of a staircase 302. As can be seen, example floor plan 102 also includes various types of semantic information, such as room names 304, structural dimensional information 306, and the location of various fixtures 308 (a bathtub is depicted in the illustrated example). Other examples of indicated semantic information include the presence and location of windows and doors, the presence and locations of closets, and descriptive text such as text 310, which may describe various aspects of the floor plan 102. In the illustrated example, text 310 calls out the presence and specifications of a wall or guardrail adjacent to the staircase 302, to prevent falls. Other descriptive text in floor plan 102 describes types and sizes of windows and aspects of other structural features that are not otherwise readily indicated graphically in floor plan 102.

Such information may be processed using techniques such as character or text recognition, and may be classified as part of semantic information 104. As explained above, such information may be useable by a machine learning system 106 (FIG. 1) to extrapolate or predict additional semantic information and/or to inform subsequent renderings as part of 3D model 108 (FIG. 1).

FIG. 3B depicts plans with semantic information 104 in the form of an electrical wiring diagram. Various symbols may graphically depict the presence and connections between electrical fixtures. For example, in the depicted diagram, wiring connections 312 illustrate how various electrical fixtures should be connected. It will be understood by a person skilled in the art that the wiring connections 312 do not necessarily depict the precise locations of wiring runs, but rather how and to what fixtures are connected, e.g. wiring connection 312 shows a connection between several lamps 314 (only one is called out) and two switches 320 (only one is called out). A person skilled in electrical work would understand that the presence of two switches 320 connected in a circuit indicated by wiring connection 312 suggests a three-way switch configuration. Similarly, a ceiling fan 316 is showed connected to a switch, and the location of various outlets 318 (only one is called out) is likewise indicated.

In some scenarios, the location of fixtures such as lamps 314, ceiling fan 316, outlets 318, and switches 320 is provided within the structure on semantic information 104. The indicated position for such fixtures may be approximately where they should be placed in the structure. This differs from wiring connection 312, which may only be depicted logically; a person skilled in electrical work would route the actual wires within the walls and ceilings in accordance with structural requirements and applicable electrical codes. Furthermore, a person skilled in the art would understand that not all electrical connections are explicitly indicated. No outlets are shown having any electrical connections. Similarly, no connections are illustrated going to a breaker box from any fixture, although an electrician would understand such connections to be essential for delivery of power. However, for purposes of generating 3D model 108 (FIG. 1), machine learning system 106 (FIG. 1) may be able to extrapolate these connections, and further may be able to extrapolate the likely locations of the various wiring connections 312. Such extrapolation may be based upon information including both industry and local electrical practice standards as well as code requirements, to name a few possible extrinsic information sources. With such building industry knowledge, machine learning system 106 may be able to predict actual wiring locations with a relatively high degree of accuracy.

Although not depicted, it will be understood by a person skilled in the art that semantic information for other building aspects, such as plumbing, mechanical, HVAC, appliances, etc., may be provided in a similar graphic format, depending upon the needs of a given embodiment. Likewise, the presence and locations of various associated aspects, e.g. plumbing locations and sizes, HVAC runs, etc., may be extrapolated from such other semantic information in conjunction with established building practices and applicable building codes.

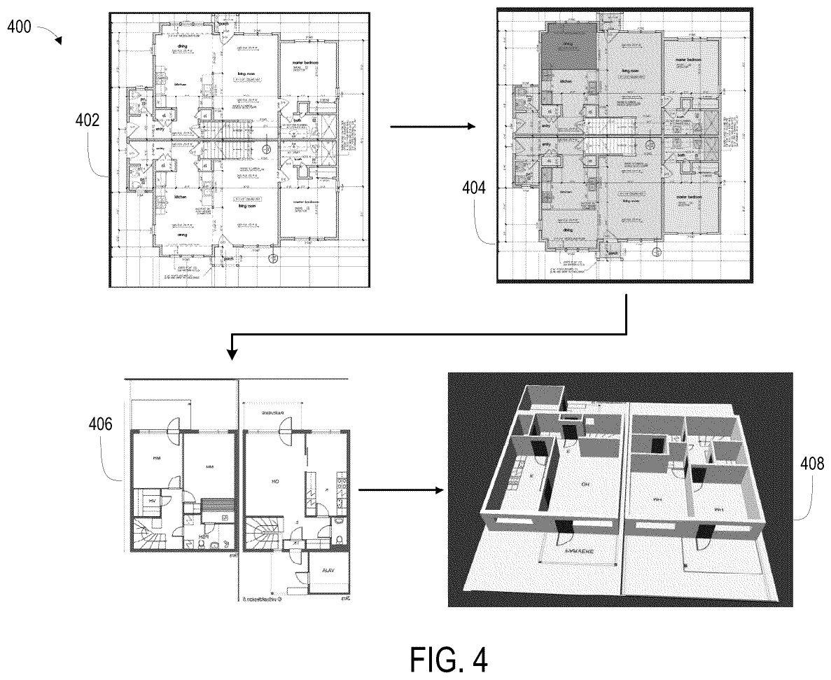

FIG. 4 depicts another example process flow 400 for creating a 3D model from a raster image of a floor plan, along with associated semantic information. An initial set of plans 402 in the form of a raster image may be supplied, such as floor plan 102 (FIG. 1). The raster plans 402 may be provided to a system for conversion of the plans into a vector image, such as part of system 100, described above with respect to FIG. 1. As discussed in FIG. 3, the raster plans 402 may include semantic information in the form of text, indicated fixtures, etc.

In embodiments, following providing of the plans 402 to a system 100 (as well as any available semantic information, such as information 104), a set of vector plans 404 is generated by the system 100, along with any predicted semantic information, as discussed above. The set of vector plans 404, in embodiments, matches the scale of the initial raster plans 402, allowing for measurements to be taken from the vector plans 404 that are comparable to similar measurements taken from the raster plans 402. Furthermore, in some embodiments, both provided semantic information (from raster plans 402 and other information 104) and predicted semantic information may be associated with the vector plans 404, such as with metadata or another suitable technique. The vector plans 404 may be in any suitable vector format, such as PDF, PostScript, a format usable by CAD or building information management software, or another vector format now known or later developed.

Once the vector plans 404 and predicted semantic information have been generated by the system, they may be used to construct a 3D model, such as 3D model 108. Such processing may proceed on a floor-by-floor basis. In some embodiments, the vector plans 404 may be used to generate a 2D floor plan 406. Where the structure comprises multiple floors, each floor may have its own set of associated raster plans 402. In such implementations, each floor may be converted into its own corresponding vector plan 402, and subsequent 2D floor plan 406. Generation of the 2D floor plan(s) 406 from the vector plans 404 may be accomplished by any suitable method. In some implementations, generation may be accomplished by identifying, from the vector plans 404, the walls on each floor to establish the 2D layout of each floor. Vector information, by its nature, includes the locations and description of each line; extraction of walls may thus be accomplished by simply identifying the lines that comprise all walls. Depending on the nature of associated semantic information, such semantic information may be used to help identify which lines comprise walls, particularly if other lines in the vector format that are not walls are present.

Depending on the specifics of a given embodiment, the subsequent 2D floor plan 406, or collection of 2D floor plans 406 for each floor, may be provided in their own format and/or separate files. In other embodiments, the 2D floor plan(s) may be stored internally or in some form of interim or proprietary format for immediate processing into a 3D model.

Finally, the 2D floor plan(s) 406 may be used to generate a 3D model 408, which may be an instance of 3D model 108 (FIG. 1). Generation of the model 408 may include extrusion of the identified walls, which may exist in an x-y plane, in a z-direction. The amount that each wall should be extruded may be ascertained from the associated semantic data, which may either have been provided or be predicted. Other aspects of the 3D model 408 may be generated and rendered on the basis of the provided and/or predicted semantic information, such as doors, windows, roofing, fixtures, appliances, cabinets, lighting, finishes, etc. As mentioned above with respect to FIG. 2, the 3D model 408 may also include renderings of otherwise hidden information, such as predicted or actual locations of structural members, HVAC ducts, wiring, plumbing, etc. Such renderings may also be determined from provided and/or predicted semantic information. In some embodiments, the system may obtain assets from remote sites, such as over the Internet, to assist in creating the 3D model 408. For example, where the plans and semantic information indicate particular appliances, fixtures, and/or finishes, such information can be used to obtain visual representations of the various features which could then be used to augment or create more realistic depictions of the features in the 3D model 408.

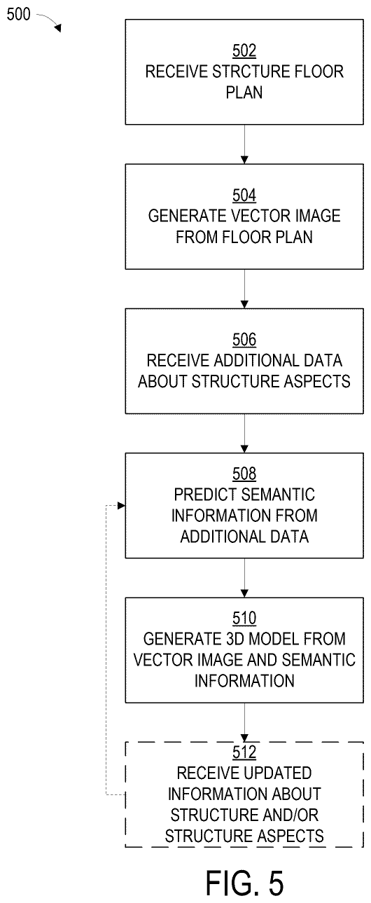

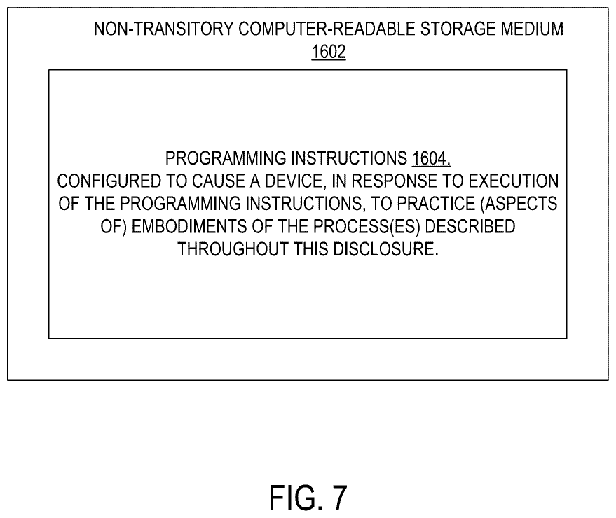

FIG. 5 is an example method 500 of the operations for generating a 3D model from a raster image of a floor plan, along with associated semantic information. The operations of method 500 may be carried out in whole or in part, depending upon the needs of a given embodiment. Further some operations may be omitted, some operations may be added, and the order of operations may be rearranged depending upon the requirements of a given embodiment. The operations of method 500 may be carried out by one or more components of an appropriate system, such as using one or more computer devices 1500 (FIG. 6) and/or executable software, such as depicted in FIG. 7. Some or all operations may be carried out by a server, or by a device within the structure, or both.

In operation 502 of the depicted embodiment, a floor plan of a structure, such as floor plan 102 (FIG. 1) is received by an implementing system, such as system 100 (FIG. 1), for processing. As discussed above with respect to FIG. 1, the floor plan of the structure may be in a suitable raster image format. The floor plan may also include embedded semantic information, e.g. text specifications, legends, etc. As discussed above, where a structure has multiple floors, there may be multiple raster images, one or more corresponding to each floor. Alternatively, some raster images may include floor plans for multiple floors, e.g. a single scan of a large plan that depicts multiple floors.

In operation 504 of the embodiment, the system generates a vector image or set of plans from the raster floor plan of the structure. This processes is described in more detail above, with respect to FIG. 4. Where a single image may have multiple floor plans, the system may be configured to distinguish each individual floor and separate them for generation of vector images for each corresponding floor. Provided the raster image of the floor plan is drawn to scale, the corresponding vector image or floor plan should likewise retain the scale of the depicted structure, and thus be useful for obtaining measurements that are relatively precise in correspondence with a physical structure that is constructed in accordance with the floor plans.

In various embodiments, determining the order of floors and which raster floor plan image corresponds to which floor, e.g. first floor, second floor, basement, etc., may be important for the creation of an accurate 3D model. With such images, the system may be able to distinguish the plans of individual floors from a single raster image or multiple raster images by reference to embedded semantic information. Such information may, in some cases, explicitly label each floor plan with its corresponding floor. In other cases, each floor may be distinguished by specific features, such as the presence of a stair well, or markings indicating features unique to a given floor, such as entry doors, garages, basement walls, roof lines, indications of areas open to lower levels, differences in footprints corresponding to different levels, and/or any other similarly suitable information that suggests where a particular floor depicted by a given raster image should fit within the overall hierarchy of structure floors.

In operation 506 of the embodiment, additional data about the structure may be received by the system. This additional information may include semantic information, such as semantic information 104. As with the aforementioned discussion of multiple floors, the semantic information may be directly correlated to a given floor, particularly where it is presented in a similar format to a wiring diagram, as illustrated in FIG. 3B.

In operation 508 of the embodiment, the system may predict additional semantic information from the received additional data as well as any semantic information provided along with the raster floor plan of the structure. This prediction process is described above in greater detail with respect to FIGS. 1-3B.

In operation 510 of the embodiment, the system may use the generated vector image, additional semantic data, and predicted semantic information to generate a 3D model, e.g. “dollhouse” type view, of the structure presented in the initial raster image(s). As mentioned above with respect to FIG. 4, the system may, in embodiments, use the semantic information, both provided and predicted, to obtain further assets from third parties and remote systems to enhance the realism of the final 3D model. Provided the floor plans are drawn to scale, the resultant 3D model should also provide a relatively scale-accurate depiction of how a physical structure built according to the plans and associated semantic information (both provided and predicted) should appear.

Finally, in operation 512 of the embodiment, updated information about the structure and or structure aspects may optionally be received. This updated and/or new information may be fed back into the system, such as to operation 508 in the depicted flowchart, where it may be used to predicted additional new semantic information, update or verify previously predicted semantic information, and/or replace or supplement previously provided semantic information. The updated information about the structure may further be used to modify or update the vector image(s) of the floor plans. Sources of the updated information may be obtained from any appropriate source and through any suitable method. In some implementations, the updated information could be obtained through a direct scan of a structure either completed or under construction that corresponds to the raster plans, such as where a user with a mobile device uses the mobile device to take pictures, video, or another type of scan of the structure.

Alternatively or additionally, the source of the updated information may include scans or raster images of revised versions of the floor plans. Such images may be provided to operation 502 rather than operation 508, as may be necessary for appropriate processing. In some embodiments, the implementing system may track the changes to the resultant vector images and/or 3D model from the initially provided set of raster plans, so that a user of the system can determine which aspects have changed over the life of the structure and its construction. It should be understood that these changes may be tracked regardless of the source of the updated information, i.e. updated raster images, mobile device scans, or another suitable source of updated building information. In some embodiments, the tracked changes may also include changes to provided and/or predicted semantic information, e.g. predicted locations of wiring may be updated in response to the moving, addition, or deletion of an electrical fixture.

FIG. 6 illustrates an example computer device 1500 that may be employed by the apparatuses and/or methods described herein, in accordance with various embodiments. As shown, computer device 1500 may include a number of components, such as one or more processor(s) 1504 (one shown) and at least one communication chip 1506. In various embodiments, one or more processor(s) 1504 each may include one or more processor cores. In various embodiments, the one or more processor(s) 1504 may include hardware accelerators to complement the one or more processor cores. In various embodiments, the at least one communication chip 1506 may be physically and electrically coupled to the one or more processor(s) 1504. In further implementations, the communication chip 1506 may be part of the one or more processor(s) 1504. In various embodiments, computer device 1500 may include printed circuit board (PCB) 1502. For these embodiments, the one or more processor(s) 1504 and communication chip 1506 may be disposed thereon. In alternate embodiments, the various components may be coupled without the employment of PCB 1502.

Depending on its applications, computer device 1500 may include other components that may be physically and electrically coupled to the PCB 1502. These other components may include, but are not limited to, memory controller 1526, volatile memory (e.g., dynamic random access memory (DRAM) 1520), non-volatile memory such as read only memory (ROM) 1524, flash memory 1522, storage device 1554 (e.g., a hard-disk drive (HDD)), an I/O controller 1541, a digital signal processor (not shown), a crypto processor (not shown), a graphics processor 1530, one or more antennae 1528, a display, a touch screen display 1532, a touch screen controller 1546, a battery 1536, an audio codec (not shown), a video codec (not shown), a global positioning system (GPS) device 1540, a compass 1542, an accelerometer (not shown), a gyroscope (not shown), a depth sensor 1548, a speaker 1550, a camera 1552, and a mass storage device (such as hard disk drive, a solid state drive, compact disk (CD), digital versatile disk (DVD)) (not shown), and so forth.

In some embodiments, the one or more processor(s) 1504, flash memory 1522, and/or storage device 1554 may include associated firmware (not shown) storing programming instructions configured to enable computer device 1500, in response to execution of the programming instructions by one or more processor(s) 1504, to practice all or selected aspects of system 100, process flow 400, or method 500 described herein. In various embodiments, these aspects may additionally or alternatively be implemented using hardware separate from the one or more processor(s) 1504, flash memory 1522, or storage device 1554.

The communication chips 1506 may enable wired and/or wireless communications for the transfer of data to and from the computer device 1500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1506 may implement any of a number of wireless standards or protocols, including but not limited to IEEE 802.20, Long Term Evolution (LTE), LTE Advanced (LTE-A), General Packet Radio Service (GPRS), Evolution Data Optimized (Ev-DO), Evolved High Speed Packet Access (HSPA+), Evolved High Speed Downlink Packet Access (HSDPA+), Evolved High Speed Uplink Packet Access (HSUPA+), Global System for Mobile Communications (GSM), Enhanced Data rates for GSM Evolution (EDGE), Code Division Multiple Access (CDMA), Time Division Multiple Access (TDMA), Digital Enhanced Cordless Telecommunications (DECT), Worldwide Interoperability for Microwave Access (WiMAX), Bluetooth, derivatives thereof, as well as any other wireless protocols that are designated as 3G, 4G, 5G, and beyond. The computer device 1500 may include a plurality of communication chips 1506. For instance, a first communication chip 1506 may be dedicated to shorter range wireless communications such as Wi-Fi and Bluetooth, and a second communication chip 1506 may be dedicated to longer range wireless communications such as GPS, EDGE, GPRS, CDMA, WiMAX, LTE, Ev-DO, and others.

In various implementations, the computer device 1500 may be a laptop, a netbook, a notebook, an ultrabook, a smartphone, a computer tablet, a personal digital assistant (PDA), a desktop computer, smart glasses, or a server. In further implementations, the computer device 1500 may be any other electronic device that processes data.

As will be appreciated by one skilled in the art, the present disclosure may be embodied as methods or computer program products. Accordingly, the present disclosure, in addition to being embodied in hardware as earlier described, may take the form of an entirely software embodiment (including firmware, resident software, micro-code, etc.) or an embodiment combining software and hardware aspects that may all generally be referred to as a “circuit,” “module” or “system.” Furthermore, the present disclosure may take the form of a computer program product embodied in any tangible or non-transitory medium of expression having computer-usable program code embodied in the medium.

FIG. 7 illustrates an example computer-readable non-transitory storage medium that may be suitable for use to store instructions that cause an apparatus, in response to execution of the instructions by the apparatus, to practice selected aspects of the present disclosure. As shown, non-transitory computer-readable storage medium 1602 may include a number of programming instructions 1604. Programming instructions 1604 may be configured to enable a device, e.g., computer 1500, in response to execution of the programming instructions, to implement (aspects of) system 100, process flow 400 or method 500 described above. In alternate embodiments, programming instructions 1604 may be disposed on multiple computer-readable non-transitory storage media 1602 instead. In still other embodiments, programming instructions 1604 may be disposed on computer-readable transitory storage media 1602, such as, signals.

Any combination of one or more computer usable or computer readable medium(s) may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to wireless, wireline, optical fiber cable, RF, etc.

Computer program code for carrying out operations of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The present disclosure is described with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable medium that can direct a computer or other programmable data processing apparatus to function in a particular manner, such that the instructions stored in the computer-readable medium produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

What is claimed is:

1. A method, comprising:
receiving, at a server over a network, a raster image of a floor plan of a structure;
identifying, by the server, semantic information of the floor plan from the raster image;
generating, by the server, a vector image from the raster image and identified semantic information by processing the raster image through a machine learning model;
generating, by the server, a 3D model from the vector image; and
updating, by the server, the vector image and 3D model in response to additional input.

2. The method of claim 1, further comprising training, prior to generating the vector image, the machine learning model.

3. The method of claim 1, wherein the additional input comprises an updated raster image of the floor plan.

4. The method of claim 1, wherein the additional input comprises a scan of a physical space corresponding to the floor plan.

5. The method of claim 1, wherein the raster image of a floor plan is a raster image of a floor plan of a first floor, the 3D model of the vector image is a 3D model of the first floor, and wherein the method further comprises:
receiving, at the server over the network, a raster image of a floor plan of a second floor of the structure;
identifying, by the server, semantic information of the floor plan of the second floor from the raster image of the floor plan of the second floor;
generating, by the server, a vector image from the raster image of the floor plan of the second floor and identified semantic information of the floor plan of the second floor;
generating, by the server, a 3D model of the vector image of the second floor; and
combining, by the server, the 3D model of the first floor with the 3D model of the second floor to create a multi-level 3D model of a structure.

6. The method of claim 1, wherein the semantic information comprises room segmentation information and non-visible structures.

7. The method of claim 6, wherein the non-visible structures include one or more of wiring, plumbing, ventilation ducts, insulation, and structural members.

8. A non-transitory computer-readable medium (CRM) comprising instructions that, when executed by the processor of an apparatus, cause the apparatus to:
receive, over a network, a raster image of a floor plan of a structure;
identify semantic information of the floor plan from the raster image;
generate a vector image from the raster image and identified semantic information by processing the raster image through a machine learning model;
generate a 3D model from the vector image; and
update the vector image and 3D model in response to additional input.

9. The CRM of claim 8, wherein the instructions are to further cause the apparatus to train, prior to generating the vector image, the machine learning model.

10. The CRM of claim 8, wherein the additional input comprises an updated raster image of the floor plan.

11. The CRM of claim 8, wherein the additional input comprises a scan of a physical space corresponding to the floor plan.

12. The CRM of claim 8, wherein the raster image of a floor plan is a raster image of a floor plan of a first floor, the 3D model of the vector image is a 3D model of the first floor, and wherein the instructions are to further cause the apparatus to:
receive a raster image of a floor plan of a second floor of the structure;
identify semantic information of the floor plan of the second floor from the raster image of the floor plan of the second floor;
generate a vector image from the raster image of the floor plan of the second floor and identified semantic information of the floor plan of the second floor;
generate a 3D model of the vector image of the second floor; and
combine the 3D model of the first floor with the 3D model of the second floor to create a multi-level 3D model of a structure.

13. The CRM of claim 8, wherein the apparatus is a server, and the raster image is received from a remote user device over a network.

14. The CRM of claim 8, wherein the additional input comprises one or more diagrams of wiring, plumbing, ventilation ducts, insulation, and structural members.

15. A system, comprising:
a server; and
a network interface in communication with the server,
wherein the server includes instructions to cause the server, when the instructions are executed by a processor of the server, to:
receive, over the network interface, a scan of a floor plan of a structure;
identify semantic information of the floor plan from the scan;
generate a vector image from the scan and identified semantic information by processing the scan through a machine learning model;
generate a 3D model from the vector image; and
update the vector image and 3D model in response to additional input.

16. The system of claim 15, wherein the scan is received from a first remote user device over the network interface, and the additional input is received from a second remote user device over the network interface.

17. The system of claim 15, wherein the instructions are to further cause the server to transmit, to a remote user device over the network interface, at least a portion of the 3D model.

18. The system of claim 15, wherein the additional input comprises a scan performed by a remote user device.

19. The system of claim 15, wherein the scan is a scan of a floor plan of a first floor of the structure, the 3D model is a 3D model of the first floor, and the instructions are to further cause the server to:
receive a scan of a floor plan of a second floor of the structure;
identify semantic information of the floor plan of the second floor from the scan of the floor plan of the second floor;
generate a vector image from the scan of the floor plan of the second floor and identified semantic information of the floor plan of the second floor;
generate a 3D model of the vector image of the second floor; and
combine the 3D model of the first floor with the 3D model of the second floor to create a multi-level 3D model of the structure.

20. The system of claim 19, wherein either or both of the scan of the first floor and the scan of the second floor comprise raster images.
